(19) United States
(12) Patent Application Publication
(10) Pub. No.: US 2026/0223554 A1
(43) Pub. Date: Jul. 30, 2026

(54) DISPLAY PANEL AND METHOD FOR MANUFACTURING THEREOF, AND DISPLAY DEVICE

(71) Applicant: Guangzhou China Star Optoelectronics Semiconductor Display Technology Co., Ltd., Guangzhou (CN)

(72) Inventors: Juncheng XIAO, Guangzhou (CN); Shan LI, Guangzhou (CN); Yuanjun HSU, Guangzhou (CN); Xiaolin YAN, Guangzhou (CN); Xiaoxing ZHANG, Guangzhou (CN)

(73) Assignee: Guangzhou China Star Optoelectronics Semiconductor Display Technology Co., Ltd., Guangzhou (CN)

(21) Appl. No.: 19/241,547

(22) Filed: Jun. 18, 2025

(30) Foreign Application Priority Data
Jan. 24, 2025 (CN) 202510122898.8

(51) Int. Cl. H10K 59/126; H10K 59/12; H10K 59/131

(52) U.S. Cl. CPC H10K 59/126; H10K 59/1201; H10K 59/131

(57) ABSTRACT

A display panel and a method for manufacturing the display panel, and a display device are provided. An interlayer dielectric layer covers a first active portion and a side of a first gate away from a substrate. The interlayer dielectric layer is provided with a first contact hole and a second contact hole. A depth of the first contact hole is less than a depth of the second contact hole. The first contact hole exposes the first active portion. The second contact hole exposes a light shielding portion. The first contact hole includes a first upper hole and a first lower hole. The second contact hole includes a second upper hole and a second lower hole. A depth of the second upper hole is equal to a depth of the first upper hole. A depth of the second lower hole is greater than a depth of the first lower hole.

### CROSS-REFERENCE TO RELATED APPLICATION

This application claims priority to Chinese Patent Application No. 202510122898.8 filed on January 24, 2025. The disclosure of the aforementioned application is herein incorporated by references in its entirety.

### TECHNICAL FIELD

The present disclosure relates to the field of display technology, and more particularly, to a display panel and a method for manufacturing the display panel, and a display device.

### BACKGROUND

In a driving backplane of an existing top-gate thin film transistor architecture, it is generally necessary to provide shallow holes and deep holes to achieve connection. The deep holes need to penetrate through a buffer layer, while the shallow holes do not need to penetrate through the buffer layer. For example, the shallow holes expose an active layer and the deep holes expose a light shielding layer. However, in order to prevent the active layer at the shallow holes from being seriously over-etched, two photomasks are used to form the shallow holes and the deep holes respectively in the art, but the use of the two photomasks will lead to an increase in manufacturing costs.

### SUMMARY

A display panel and a method for manufacturing the display panel, and a display device are provided by the embodiments of the present disclosure, which can reduce a risk of an active layer being seriously over-etched while saving a photomask for forming shallow holes and deep holes.

In a first aspect, a display panel is provided by the embodiments of the present disclosure. The display panel includes:

a substrate;

a light shielding portion disposed on the substrate;

a buffer layer disposed on a side of the light shielding portion away from the substrate;

a first active portion, disposed on a side of the buffer layer away from the substrate;

a first gate disposed in a different layer from the first active portion; and

an interlayer dielectric layer covering the first active portion and a side of the first gate away from the substrate, where the interlayer dielectric layer is provided with a first contact hole and a second contact hole, a depth of the first contact hole is less than a depth of the second contact hole, the first contact hole penetrates through the interlayer dielectric layer and exposes the first active portion, and the second contact hole penetrates through the interlayer dielectric layer and the buffer layer and exposes the light shielding portion.

In a thickness direction of the display panel, the first contact hole includes a first upper hole and a first lower hole. The first lower hole penetrates through a part of the interlayer dielectric layer and a part of the first active portion. The first upper hole is communicated with a side of the first lower hole. A width of an opening of the first lower hole is less than a width of an opening of the first upper hole.

In the thickness direction of the display panel, the second contact hole includes a second upper hole and a second lower hole. The second lower hole penetrates through a part of the interlayer dielectric layer and the buffer layer. The second upper hole is communicated with a side of the second lower hole away from the substrate. A width of an opening of the second lower hole is less than a width of an opening of the second upper hole. A depth of the second upper hole is equal to a depth of the first upper hole. A depth of the second lower hole is greater than a depth of the first lower hole.

In a second aspect, a method for manufacturing the display panel is further provided by the embodiments of the present disclosure. The method includes following steps:

forming a light shielding portion, a buffer layer, a first active portion, a first insulating portion, a first gate, and an interlayer dielectric layer stacked on the substrate in sequence; and

performing two dry etching processes on the interlayer dielectric layer using a same photomask to form a first contact hole and a second contact hole, where a depth of the first contact hole is less than a depth of the second contact hole, the first contact hole penetrates through the interlayer dielectric layer and exposes the first active portion, the second contact hole penetrates through the interlayer dielectric layer and the buffer layer and exposes the light shielding portion, the first contact hole includes a first upper hole and a first lower hole, the first lower hole penetrates through a part of the interlayer dielectric layer and a part of the first active portion, the first upper hole is communicated with a side of the first lower hole away from the substrate, a width of an opening of the first lower hole is less than a width of an opening of the first upper hole, the second contact hole includes a second upper hole and a second lower hole, the second lower hole penetrates through a part of the interlayer dielectric layer and the buffer layer, the second upper hole is communicated with a side of the second lower hole away from the substrate, a width of an opening of the second lower hole is less than a width of an opening of the second upper hole, a depth of the second upper hole is equal to a depth of the first upper hole, and a depth of the second lower hole is greater than a depth of the first lower hole.

In a third aspect, a display device is further provided by the embodiments of the present disclosure. The display device includes the display panel described in any one of the above embodiments.

### BRIEF DESCRIPTION OF THE DRAWINGS

FIG. 1 is a schematic structural view of a display panel according to the embodiments of the present disclosure.

FIG. 2 is a schematic partial structural view of a display panel according to the embodiments of the present disclosure.

FIG. 3 is a schematic enlarged view of part M1 in FIG. 2.

FIG. 4 is a schematic enlarged view of part M2 in FIG. 2.

FIG. 5 is another schematic structural view of a display panel according to the embodiments of the present disclosure.

FIG. 6 is another schematic partial structural view of a display panel according to the embodiments of the present disclosure.

FIG. 7 is a schematic enlarged view of part M3 in FIG. 6.

FIG. 8 is a schematic enlarged view of part M4 in FIG. 6.

FIG. 9 is a schematic view showing a step B01 of a method for manufacturing a display panel according to the embodiments of the present disclosure.

FIG. 10 is a schematic view showing a step B021 of a method for manufacturing a display panel according to the embodiments of the present disclosure.

FIG. 11 is a schematic view showing a step B022 of a method for manufacturing a display panel according to the embodiments of the present disclosure.

FIG. 12 is a schematic view showing a step B03 of a method for manufacturing a display panel according to the embodiments of the present disclosure.

FIG. 13 is a schematic structural view of a display device according to the embodiments of the present disclosure.

### DETAILED DESCRIPTION

The technical solutions in the embodiments of the present disclosure will be described clearly and completely hereafter with reference to accompanying drawings. Apparently, the described embodiments are only a part of but not all embodiments of the present disclosure. According to the embodiments in the present disclosure, all other embodiments obtained by those skilled in the art without making any creative effort shall fall within the protection scope of the present disclosure. Furthermore, it should be understood that the specific embodiments described here are only for the purpose of illustration and explanation of the present disclosure and are not intended to limit the present disclosure. In the present disclosure, location terms such as “up” and “down”, without description to the contrary, generally refer to up and down in the actual use or operating state of the device, specifically the drawing direction in the drawings. Terms “inside” and “outside” are for the contour of the device. The terms “first,” “second,” “third,” etc., are used only for marking purposes and do not imply any numerical requirement or establish order.

A display panel and a method for manufacturing the display panel, and a display device are provided by the embodiments of the present disclosure, which will be described in detail below. It should be explained that a describing order of the following embodiments is not a limit to a priority of the embodiments.

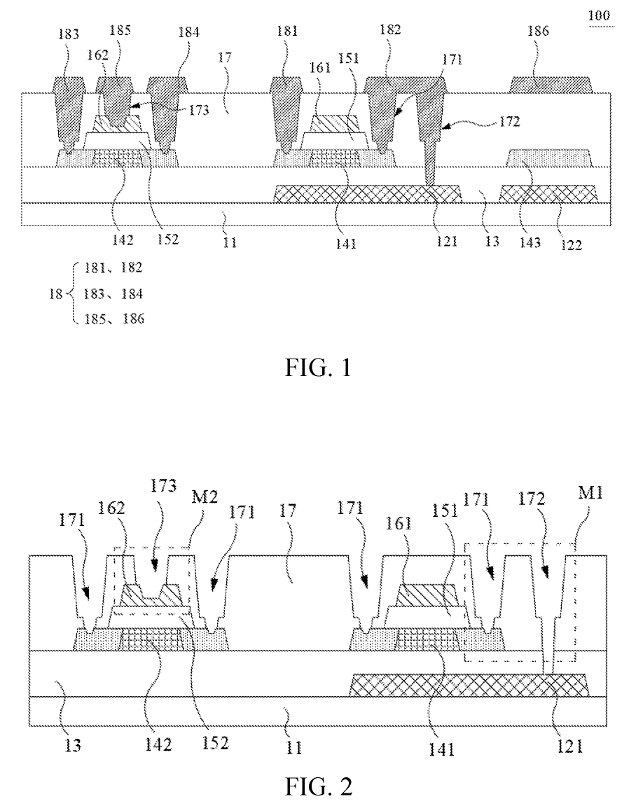

Referring to FIGS. 1 to 4, a display panel 100 is provided by the embodiments of the present disclosure. The display panel 100 includes a substrate 11, a light shielding portion 121, a buffer layer 13, a first active portion 141, a first gate 161, and an interlayer dielectric layer 17.

The light shielding portion 121 is disposed on the substrate 11. The buffer layer 13 is disposed on a side of the light shielding portion 121 away from the substrate 11. The first active portion 141 is disposed on a side of the buffer layer 13 away from substrate 11. The first gate 161 is disposed in a different layer from the first active portion 141. The interlayer dielectric layer 17 covers the first active portion 141 and a side of the first gate 161 away from the substrate 11.

The interlayer dielectric layer 17 is provided with a first contact hole 171 and a second contact hole 172. A depth of the first contact hole 171 is less than a depth of the second contact hole 172. The first contact hole 171 penetrates through the interlayer dielectric layer 17 and exposes the first active portion 141. The second contact hole 172 penetrates through the interlayer dielectric layer 17 and the buffer layer 13 and exposes the light shielding portion 121.

The first contact hole 171 includes a first upper hole 1a and a first lower hole 1b. The first lower hole 1b penetrates through a part of the interlayer dielectric layer 17 and a part of the first active portion 141. The first upper hole 1a is communicated with a side of the first lower hole 1b away from the substrate 11. A width k1 of an opening of the first lower hole 1b is less than a width k2 of an opening of the first upper hole 1b.

The second contact hole 172 includes a second upper hole 2a and a second lower hole 2b. The second lower hole 2b penetrates through a part of the interlayer dielectric layer 17 and the buffer layer 13. The second upper hole 2a is communicated with a side of the second lower hole 2b away from the substrate 11. A width k3 of an opening of the second lower hole 2b is less than a width k4 of an opening of the second upper hole 2a. A depth of the second upper hole 2a is equal to a depth of the first upper hole 1a. A depth of the second lower hole 2b is greater than a depth of the first lower hole 1b.

In the display panel 100 provided by the embodiments of the present disclosure, an etching process is performed on the interlayer dielectric layer 17 using the same photomask to form the first contact hole 171 exposing the first active portion 141 and the second contact hole 172 exposing the light shielding portion 121, thereby saving photomasks. In addition, the depth of the first upper hole 1a of the first contact hole 171 is equal to the depth of the second upper hole 2a of the second contact hole 172, the depth of the first lower hole 1b of the first contact hole 171 is less than the depth of the second lower hole 2b of the second contact hole 172, and the first lower hole 1b of the first contact hole 171 penetrates through the part of the first active portion 141, thereby reducing a degree to which the first active portion 141 is etched.

It can be understood that the deeper the degree to which the first active portion 141 is over-etched with the first lower hole 1b, the larger the width k1 of the opening of the first lower hole 1b is, which may reduce the stability and service life of a thin-film transistor. Furthermore, when the first contact hole 171 serves as an output terminal via hole, a risk of leakage current in a thin-film transistor device can further be increased. As such, considering the leakage current, the stability, and the service life of the thin-film transistor, it is necessary to reduce the risk of the first active portion 141 being over-etched with the first lower hole 1b.

Therefore, in some embodiments of the present disclosure, in the thickness direction of the display panel 100, a ratio of the depth of the first lower hole 1b penetrating through the first active portion 141 to a thickness of the first active portion 141 is less than or equal to 3/5, so as to reduce the degree to which the first active portion 141 is etched, thereby reducing the risk of leakage current and the risk of the instability and short service life of the device. In addition, the depth of the first lower hole 1b penetrating through the first active portion 141 is less than or equal to 3/5 of the thickness of the first active portion 141, so that contact areas between the source and the drain with the first active portion 141 can be increased, the current control capability of the device can be improved, and the contact failure can be reduced. Furthermore, a resistance of source and drain regions of the first active portion 141 can also be reduced, thereby improving a response speed of the device.

Optionally, the depth of the first lower hole 1b penetrating through the first active portion 141 is equal to 3/5, 2/5, 1/5, 1/6, 1/7, 1/8, 1/9, 1/10, etc. of the thickness of the first active portion 141.

Optionally, in some embodiments of the present disclosure, in the thickness direction of the display panel 100, the depth of the first lower hole 1b penetrating through the first active portion 141 ranges from 1 nm to 30 nm. This arrangement can further reduce the risk of leakage current and the risk of the instability and short service life of the device, improve the current control capability and the response speed of the device, and reduce a risk of poor contact.

Optionally, the depth of the first lower hole 1b penetrating through the first active portion 141 may be 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, etc.

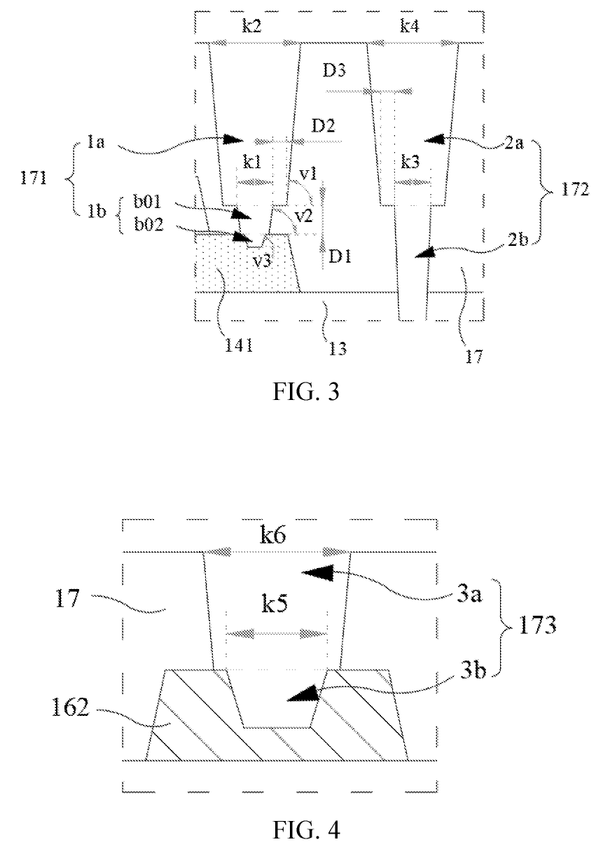

Referring to FIGS. 2 and 3, optionally, in some embodiments of the present disclosure, in the thickness direction of the display panel, a distance from an end surface of the opening of the first lower hole 1b to the first active portion 141 is a first distance D1, and the first distance D1 ranges from 1 nm to 60 nm.

It should be understood that during the first etching process on the first contact hole 171 and the second contact hole 172, a gas with a high etching rate is selected to etch the interlayer dielectric layer 17 to shorten manufacturing time. Since the second lower hole 2b is relatively deep and an etching time and the etching gas of the first lower hole 1b and the second lower hole 2b are consistent, respectively, the larger the first distance D1 is, the greater a distance from a blind hole after the first etching process to the first active portion 141. Thus the first lower hole 1b formed by the second etching process has a larger distance for buffering when the first active portion 141 is over-etched, and the degree that the first active portion 141 is over-etched can be reduced. Besides, a rate of etching the interlayer dielectric layer 17 during the second etching process is relatively slow, and the time for forming the first contact hole 171 and the second contact hole 172 is prolonged.

As such, considering the balance between reduction of the degree to which the first active portion 141 is over-etched and the time required for manufacturing the contact holes, the first distance D1 can be selected to range from 1 nm to 60 nm, e.g., 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 32 nm, 34 nm, 36 nm, 38 nm, 40 nm, 42 nm, 44 nm, 46 nm, 48 nm, 50 nm, 52 nm, 54 nm, 56 nm, 58 nm, or 60 nm, etc.

Optionally, in some embodiments of the present disclosure, a distance from the opening of the first lower hole 1b to a hole wall of the first upper hole 1a is a second distance D2, and the second distance D2 ranges from 0.1 μm to 2 μm.

It can be understood that the larger the second distance D2 is, the smaller the opening width k1 of the first lower hole 1b is, which means the shallower the degree to which the first active portion 141 is over-etched with the first lower hole 1b. The larger the second distance D2 is, the larger a buffer region between the first upper hole 1a and the first lower hole 1b is, so that a risk that film layers subsequently covering the first contact hole 171 are broken may be reduced. Furthermore, as the second distance D2 increases, a layout area of the first contact hole 171 increases, and an aperture ratio decreases.

As such, considering the balance between the reduction of the degree to which the first active portion 141 is etched, the risk of the subsequent film layers being broken, and the aperture ratio, the second distance D2 is selected to range from 0.1 μm to 2 μm, such as 0.1 μm, 0.2 μm, 0.3 μm, 0.4 μm, 0.5 μm, 0.6 μm, 0.7 μm, 0.8 μm, 0.9 μm, 1 μm, 1.1 μm, 1.2 μm, 1.3μm, 1.4 μm, 1.5 μm, 1.6 μm, 1.7 μm, 1.8 μm, 1.9 μm, or 2 μm.

Optionally, in some embodiments of the present disclosure, a distance from the opening of the second lower hole 2b to a hole wall of the second upper hole 2a is a third distance D3, and the second distance D2 is equal to the third distance D3.

Since both the first lower hole 1b and the second lower hole 2b are etched and formed under same etching conditions, the third distance D3 is equal to the second distance D2.

Optionally, in some embodiments of the present disclosure, considering the balance between the risk of the subsequent film layers being broken and the aperture ratio, the second distance D3 is selected to range from 0.1 μm to 2 μm, such as 0.1 μm, 0.2 μm, 0.3 μm, 0.4 μm, 0.5 μm, 0.6 μm, 0.7 μm, 0.8 μm, 0.9 μm, 1 μm, 1.1 μm, 1.2 μm, 1.3 μm, 1.4 μm, 1.5 μm, 1.6 μm, 1.7 μm, 1.8 μm, 1.9 μm, or 2 μm.

Optionally, in some embodiments of the present disclosure, the first lower hole 1b includes a first sub-hole b01 and a second sub-hole b02. The first sub-hole b01 is communicated with the first upper hole 1a. The second sub-hole b02 is communicated with a side of the first sub-hole b01 close to the substrate 11. The second sub-hole b02 is disposed in the first active portion 141. A width of an opening of the second sub-hole b02 is less than a width of an opening of the first sub-hole b01.

It can be understood that during the process of etching the interlayer dielectric layer 17 and the first active portion 141, a gas having a relatively large etching selectivity ratio is selected for etching to reduce the etching of the first active portion 141 and speed up the etching of the interlayer dielectric layer 17, so that a rate of etching the interlayer dielectric layer 17 and the buffer layer 13 by the etching gas is greater than a rate of etching the first active portion 141 by the etching gas. Thus the width of the opening of the second sub-hole b02 is less than the width of the opening of the first sub-hole b01. The width of the opening of the first sub-hole b01 is the width k1 of the opening of the first lower hole 1b.

That is, the width of the opening of the second sub-hole b02 is less than the width of the opening of the first sub-hole b01, so as to reduce the degree to which the first active portion 141 is over-etched with the first lower hole 1b and improve the stability and service life of the thin film transistor device.

Optionally, in some embodiments of the present disclosure, an inclination angle v1 of a hole wall of the first upper hole 1a is greater than an inclination angle v2 of a hole wall of the first sub-hole b01, and the inclination angle v2 of the hole wall of the first sub-hole b01 is greater than an inclination angle v3 of a hole wall of the second sub-hole b02.

It can be understood that in the thickness direction of the display panel 100, from the first upper hole 1a to the second sub-hole b02, a gradient of the inclination angle of the hole wall gradually decreases, so that a slope of the hole wall gradually becomes gentler, thereby reducing the risk of the subsequent film layers (the second electrode) being broken when covering the first contact hole 171.

Optionally, in some embodiments of the present disclosure, the depth of the first upper hole 1a is greater than a depth of the first sub-hole b01, and the depth of the first sub-hole b01 is greater than a depth of the second sub-hole b02.

It can be understood that in three-section hole regions of the first upper hole 1a, the first sub-hole b01, and the second sub-hole b02 in the first contact hole 171, the first upper hole 1a is in an upper section, the first sub-hole b01 is in a middle section, and the second sub-hole b02 is in a lower section. That is, a position of the second sub-hole b02 is in the deepest section region of the first contact hole 171, and a position of the first upper hole 1a is in the shallowest section region of the first contact hole 171. As such, the depth of the first upper hole 1a, the depth of the first sub-hole b01, and the depth of the second sub-hole b02 gradually decrease, so that a proportion of the deep section hole region is reduced to reduce the risk of the second electrode being broken.

Optionally, in some embodiments of the present disclosure, the display panel 100 further includes a second active portion 142, a second gate 162, a first insulating portion 151, a second insulating portion 152, and a first metal layer 18. The first insulating portion 151 is disposed on a side of the first active portion 141 away from the substrate 11. The second active portion 142, the second insulating portion 152, and the second gate 162 are sequentially stacked on the side of the buffer layer 13 away from the substrate 11. The interlayer dielectric layer 17 covers the first gate 161, the second gate 162, and the buffer layer 13.

The first metal layer 18 is disposed on a side of the interlayer dielectric layer 17 away from the substrate 11. The first metal layer 18 includes a first electrode 181, a second electrode 182, a third electrode 183, and a fourth electrode 184. The first electrode 181 is connected to one side of the first active portion 141 through one first contact hole 171, the second electrode 182 is connected to the other side of the first active portion 141 through another first contact hole 171, and the other end of the second electrode 182 is connected to the light shielding portion 121 through one second contact hole 172. The third electrode 183 is connected to one side of the second active portion 142 through yet another one first contact hole 171. The fourth electrode 184 is connected to the other side of the second active portion 142 through yet another first contact hole 171.

The first active portion 141, the first gate 161, the first electrode 181, and the second electrode 182 constitute a first thin film transistor. The first thin film transistor is located in a display region of the display panel 100. The second active portion 142, the second gate 162, the third electrode 183, and the fourth electrode 184 constitute a second thin film transistor. The second thin film transistor is located in a gate driving circuit region of the display panel 100.

Referring to FIGS. 1 and 4, optionally, in some embodiments of the present disclosure, the first metal layer 18 further includes a first peripheral trace 185. The interlayer dielectric layer 17 is further provided with a third contact hole 173 exposing the second gate 162. A depth of the third contact hole 173 is less than the depth of the first contact hole 171. The first peripheral trace 185 is connected to the second gate 162 through the third contact hole 173.

The third contact hole 173 includes a third upper hole 3a and a third lower hole 3b. The third lower hole 3b is communicated with a side of the third upper hole 3a close to the substrate 11. A width k5 of an opening of the third lower hole 3b is less than a width k6 of an opening of the third upper hole 3a. The third lower hole 3b penetrates through a part of the second gate 162. A depth of the third lower hole 3b is greater than a depth of the first lower hole 1b penetrating through the first active portion 141.

It can be understood that the third lower hole 3b penetrates through the part of the second gate 162, and the depth of the third lower hole 3b is greater than the depth of the first lower hole 1b, thereby improving a contact area between the first peripheral trace 185 and the second gate 162, and improving a contact yield of the first peripheral trace 185 and the second gate 162. Furthermore, a contact impedance of the first peripheral trace 185 and the second gate 162 is reduced, thereby improving a response speed of the second thin film transistor.

Optionally, in some embodiments, the display panel 100 further includes a first electrode plate 122 and a second electrode plate 143. The first metal layer 18 further includes a third electrode plate 186. The first electrode plate 122 and the third electrode plate 186 form capacitors with the second electrode plate 143, respectively.

The first electrode plate 122 and the light shielding portion 121 are disposed in a same layer and made of a same material. The second electrode plate 143, the first active portion 141, and the second active portion 142 are disposed in a same layer, and all of them include a semiconductor material.

Optionally, in some embodiments of the present disclosure, a thickness of the light shielding portion 121 and a thickness of the first electrode plate 122 may range from 10 nm to 800 nm, respectively, such as 10 nm, 100 nm, 200 nm, 300 nm, 400 nm, 500 nm, 600 nm, 700 nm, or 800 nm, respectively. The light shielding portion 121 and the first electrode plate 122 may be equal in thickness.

Materials of the light shielding portion 121 and the first electrode plate 122 may each be at least one of molybdenum, a molybdenum-titanium alloy, copper, aluminum, and titanium. The light shielding portion 121 and the first electrode plate 122 may be a single film layer or a multi-film layer stacked structure.

A thickness of the buffer layer 13 may range from 10 nm to 800 nm, such as 10 nm, 100 nm, 200 nm, 300 nm, 400 nm, 500 nm, 600 nm, 700 nm, or 800 nm. A material of the buffer layer 13 may be at least one of silicon nitrogen and silicon oxygen. The buffer layer 13 may be a single film layer or a multi-film layer stacked structure.

A thickness of each of the first active portion 141, the second active portion 142, and the second plate 143 ranges from 10 nm to 50 nm, such as 10 nm, 20 nm, 30 nm, 40 nm, or 50 nm. Optionally, the first active portion 141, the second active portion 142, and the second electrode plate 143 are equal in thickness.

The first active portion 141, the second active portion 142, and the second electrode plate 143 are made of semiconductor materials, and each of them includes at least two types from indium oxide, gallium oxide, zinc oxide, and titanium-niobium oxide.

A thickness of each of the first insulation portion 151 and the second insulation portion 152 ranges from 10 nm to 800 nm, such as 10 nm, 100 nm, 200 nm, 300 nm, 400 nm, 500 nm, 600 nm, 700 nm, or 800 nm. A material of each of the first insulating portion 151 and the second insulating portion 152 may be at least one of silicon nitrogen and silicon oxygen. Each of the first insulating portion 151 and the second insulating portion 152 may be a single film layer or a multi-film layer stacked structure. Optionally, the first insulating portion 151 and the second insulating portion 152 are the same in thickness, material, and film structure, respectively.

A thickness of each of the first gate 161 and the second gate 162 may range from 10 nm to 800 nm, such as 10 nm, 100 nm, 200 nm, 300 nm, 400 nm, 500 nm, 600 nm, 700 nm, or 800 nm. The first gate 161 and the second gate 162 may be equal in thickness. The thickness of the first gate 161 and the thickness of the second gate 162 are both greater than the thickness of the first active portion 141.

A material of each of the first gate 161 and the second gate 162 may be at least one of molybdenum, molybdenum-titanium alloy, copper, aluminum, or titanium. The first gate 161 and the second gate 162 can be a single film layer or a multi-film layer stacked structure. The first gate 161 and the second gate 162 are the same in material and film structure, respectively.

A thickness of the interlayer dielectric layer 17 may range from 10 nm to 800 nm, such as 10 nm, 100 nm, 200 nm, 300 nm, 400 nm, 500 nm, 600 nm, 700 nm, or 800 nm. A material of the interlayer dielectric layer 17 may be at least one of silicon nitrogen and silicon oxygen. The interlayer dielectric layer 17 may be a single film layer or a multi-film layer stacked structure. Optionally, the material of the interlayer dielectric layer 17 may be the same as the material of the buffer layer 13.

A thickness of the first metal line layer 18 ranges from 10 nm to 800 nm, such as 10 nm, 100 nm, 200 nm, 300 nm, 400 nm, 500 nm, 600 nm, 700 nm, or 800 nm. A material of the first metal line layer 18 may be at least one of molybdenum, molybdenum-titanium alloy, copper, aluminum, or titanium. The first metal line layer 18 may be a single film layer or a multi-film layer stacked structure.

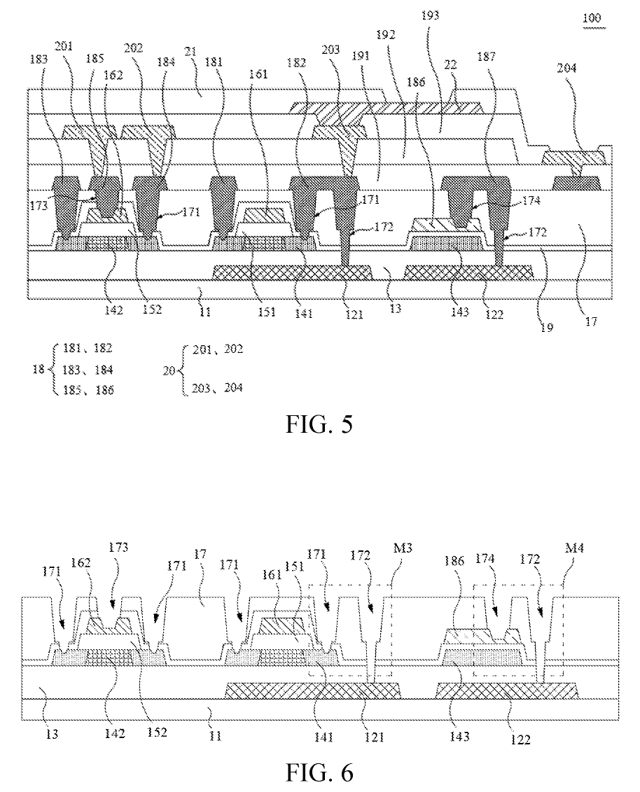

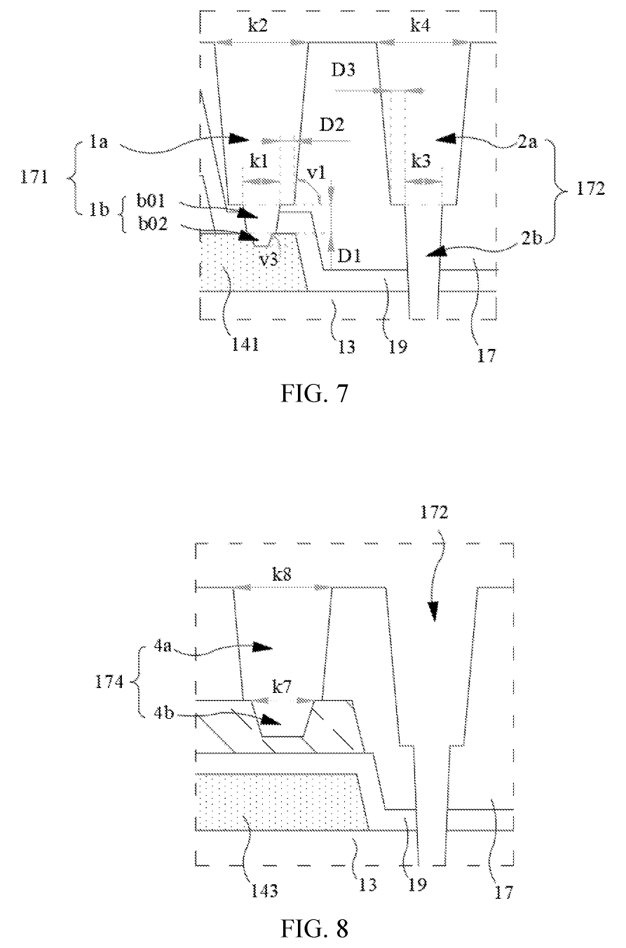

Please refer to FIGS. 5 to 8. FIG. 5 shows another schematic structural view of the display panel 100 according to the embodiments of the present disclosure. FIG. 6 is a schematic partial view of the display panel 100 in FIG. 5. FIG. 7 is a schematic enlarged view of part M3 in FIG. 6. FIG. 8 is a schematic enlarged view of part M4 in FIG. 6.

In FIGS. 5 and 8, parts different from those of the embodiments mentioned above will be described, to avoid redundant description.

Referring to FIGS. 5 to 8, compared to the above embodiments, in some embodiments of the present disclosure, the display panel 100 further includes a second insulating layer 19.

The second insulating layer 19 covers the first gate 161, the second gate 162, the second electrode plate 143, and the buffer layer 13. The third electrode plate 186 is disposed on a side of the second insulating layer 19 away from the substrate 11 and forms a capacitor with the second electrode plate 143. The interlayer dielectric layer 17 covers the second insulating layer 19 and the third electrode plate 186.

The first metal layer 18 further includes a connection line 187. The interlayer dielectric layer 17 further includes a fourth contact hole 174 exposing the third electrode plate 186 and another second contact hole 172 exposing the first electrode plate 122. The first contact hole 171 and the second contact hole 172 further penetrate through the second insulating layer 19. One end of the connection line 187 is connected to the third electrode plate 186 through the fourth contact hole 174, and the other end of the connection line 187 is connected is connected to the first electrode plate 122 through the another second contact hole 172.

The fourth contact hole 174 includes a fourth upper hole 4a and a fourth lower hole 4b. The fourth lower hole 4b is communicated with a side of the fourth upper hole 4a close to the substrate 11. A width k7 of an opening of the fourth lower hole 4b is less than a width k8 of an opening of the fourth upper hole 4a. The fourth lower hole 4b penetrates through a part of the second electrode plate 186. A depth of the fourth lower hole 4b is greater than the depth of the first lower hole 1b penetrating through the first active portion 141.

It can be understood that the fourth lower hole 4b penetrates through the part of the third electrode plate 186, and the depth of the fourth lower hole 4b is greater than the depth of the first lower hole 1b, so that a contact area between the connection line 187 and the third electrode plate 186 is improved, and a contact yield between the connection line 187 and the third electrode plate 186 is improved. Furthermore, a contact impedance between the connection line 187 and the third electrode plate 186 is reduced, thereby improving a response speed of the capacitor.

In some embodiments, the display panel 100 further includes a passivation layer 191, a first planarization layer 192, a second metal layer 20, a second planarization layer 193, a pixel definition layer 21, and an anode 22 sequentially disposed on a side of the first metal layer 18 away from the substrate 11.

Optionally, the second metal layer 20 includes a second outer peripheral trace 201 and a third outer peripheral trace 202. The second outer peripheral trace 201 is connected to the first outer peripheral trace 185. The third outer peripheral trace 202 is connected to the fourth electrode 184.

The first outer peripheral trace 185, the second outer peripheral trace 201, and the third outer peripheral trace 202 are all located in the gate driving circuit region, so as to reduce a width of a bazel.

Optionally, the second metal layer 20 further includes a transfer portion 203 and a bonding pad 204. The anode 22 is connected to the transfer portion 203, and the transfer portion 203 is connected to the second electrode 182. The bonding pad 204 is located in a bonding region of the display panel 100 and is configured to be bonded to a chip or a circuit board.

Accordingly, a method for manufacturing the display panel is further provided by the embodiments of the present disclosure. The method for manufacturing the display panel is configured to manufacture the display panel 100 in any one of the above-mentioned embodiments.

The method for manufacturing the display panel includes steps as follows.

At step B01, a light shielding portion 121, a buffer layer 13, a first active portion 141, a first insulating portion 151, a first gate 161, and an interlayer dielectric layer 17 are formed on the substrate 11 in sequence.

At step B02, two dry etching processes are performed on the interlayer dielectric layer 17 using a same photomask to form a first contact hole 171 and a second contact hole 172. A depth of the first contact hole 171 is less than a depth of the second contact hole 172. The first contact hole 171 penetrates through the interlayer dielectric layer 17 and exposes the first active portion 141. The second contact hole 172 penetrates through the interlayer dielectric layer 17 and the buffer layer 13 and exposes the light shielding portion 121. The first contact hole 171 includes a first upper hole 1a and a first lower hole 1b. The first lower hole 1b penetrates through a part of the interlayer dielectric layer 17 and a part of the first active portion 141. The first upper hole 1a is communicated with a side of the first lower hole 1b away from the substrate 11. A width k1 of an opening of the first lower hole 1b is less than a width k2 of an opening of the first upper hole 1a. The second contact hole 172 includes a second upper hole 2a and a second lower hole 2b. The second lower hole 2a penetrates through a part of the interlayer dielectric layer 17 and the buffer layer 13. The second upper hole 2a is communicated with a side of the second lower hole 2b away from the substrate 11. A width k3 of an opening of the second lower hole 2b is less than a width k4 of an opening of the second upper hole 2a. A depth of the second upper hole 2a is equal to a depth of the first upper hole 1a. A depth of the second lower hole 2b is greater than a depth of the first lower hole 1b.

In the method for manufacturing the display panel 100 provided by the embodiments of the present disclosure, an etching process is performed on the interlayer dielectric layer 17 using the same photomask to form the first contact hole 171 exposing the first active portion 141 and the second contact hole 172 exposing the light shielding portion 121, thereby saving photomasks. In addition, the depth of the first lower hole 1b of the first contact hole 171 is less than the depth of the second lower hole 2b of the second contact hole 172, and the first lower hole 1b of the first contact hole 171 penetrates through the part of the first active portion 141, thereby reducing a degree to which the first active portion 141 is etched.

Hereinafter, the method for manufacturing the display panel 100 will be described by taking the display panel 100 in the embodiments corresponding to FIG. 1 as an example.

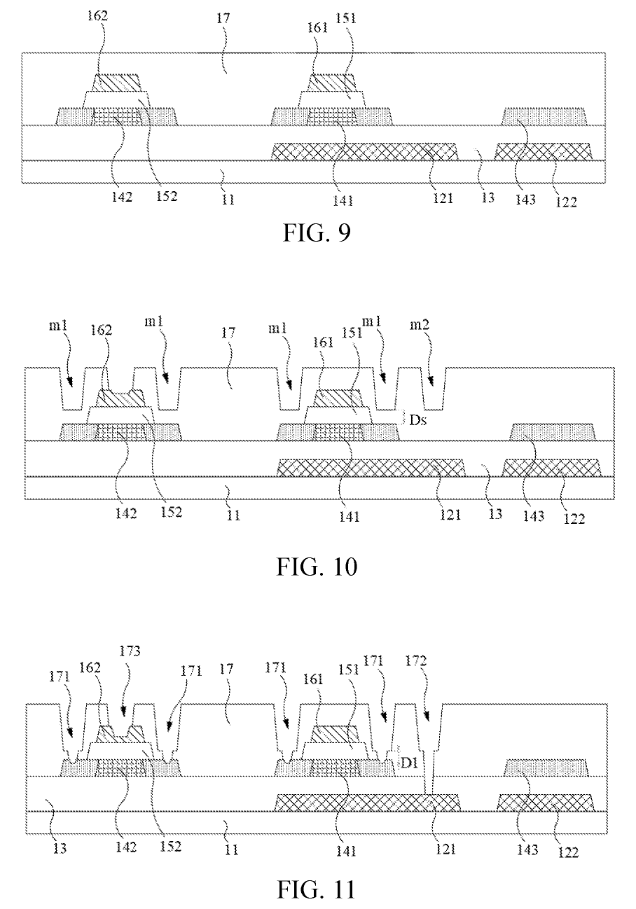

Referring to FIG. 9, at the step B01, the light shielding portion 121, the buffer layer 13, the first active portion 141, the first insulating portion 151, the first gate 161, and the interlayer dielectric layer 17 are formed on the substrate 11 in sequence.

A material of the buffer layer 13 and a material of the interlayer dielectric layer 17 are the same or have similar chemical characteristics, which is convenient for the second dry etching process.

This then proceeds to the step B02.

At the step B02, two dry etching processes are performed on the interlayer dielectric layer 17 using the same photomask to form the first contact hole 171 and the second contact hole 172.

Optionally, the step B02 includes steps as follows.

Referring to FIG. 10, at step B021, a first dry etching process is performed on the interlayer dielectric layer 17 using the photomask to form a first blind hole m1 corresponding to the first active portion 141 and a second blind hole m2 corresponding to the light shielding portion 121. A depth of the first blind hole m1 is equal to a depth of the second blind hole m2. A distance from a bottom of the first blind hole m1 to the first active portion 141 is a set distance Ds, and the set distance Ds ranges from 10 nm to 80 nm.

Optionally, the first dry etching process may include SF6 and Cl2, or based on SF6 and Cl2, increase O2 or other etching gases.

It should be noted that an etching selectivity ratio of the etching gases is an etching rate of the interlayer dielectric layer 17 to an etching rate of the first active portion 141. Since only the interlayer dielectric layer 17 is etched during the first dry etching process, the etching selectivity ratio of the first dry etching is set to be less than 4/1, so as to improve the etching rate of the interlayer dielectric layer 17 and the etching uniformity and shorten etching time of the interlayer dielectric layer 17.

It should be understood that the set distance Ds is a condition for switching to the second dry etching process, and as long as a distance from the first blind hole m1 formed by the first dry etching process to the first active portion 141 satisfies the set distance Ds, the first dry etching process is transferred to the second dry etching process.

The set distance Ds ranges from 10 nm to 80 nm, so as to prevent the first blind hole m1 from being too close to the first active portion 141, which would otherwise cause that the first active portion 141 is over-etched too much by the subsequent second etching, and thus the manufacturing process will not last too long.

Optionally, the set distance Ds may be 10 nm, 15 nm, 20 nm, 25 nm, 30 nm, 35 nm, 40 nm, 45 nm, 50 nm, 55 nm, 60 nm, 65 nm, 70 nm, 75 nm, or 80 nm.

This then proceeds to the step B022.

Referring to FIG. 11, at the step B022, two dry etching processes are performed on the interlayer dielectric layer 17 using the same photomask to form the first contact hole 171 and the second contact hole 172. A distance from an end surface of the opening of the first lower hole 1b to the first active portion 141 is a first distance D1, and the first distance D1 ranges from 1 nm to 60 nm. An etching rate of the interlayer dielectric layer 17 during the second dry etching process is greater than an etching rate of the first active portion 141 during the second dry etching process.

Optionally, the first dry etching process may include CF₄ and O₂, or other etching gases.

Since a purpose of the second dry etching process is to accelerate the etching rate of the interlayer dielectric layer 17 and the buffer layer 13 and slow down the etching rate of the first active portion 141, the degree to which the first active portion 141 is over-etched is reduced while the buffer layer 13 is etched through. As such, the etching selectivity ratio of the second dry etching process is set to be greater than 4/1.

Furthermore, during the second dry etching process, a rate at which the etching gas etches the second gate 162 is greater than a rate at which the first active portion 141 is etched, so that the depth to which the second gate 162 is etched is greater than the depth to which the first active portion 141 is etched.

Optionally, a thickness of the second gate 162 is greater than a thickness of the first active portion 141, so as to prevent the second gate 162 from being etched through.

In addition, in some embodiments, since the etching rate of the interlayer dielectric layer 17 during the first dry etching process is greater than the etching rate of the interlayer dielectric layer 17 during the second dry etching process, the etching rate of the interlayer dielectric layer 17 during the second dry etching is greater than the etching rate of the first active portion 141 during the second dry etching. As such, during manufacturing processes corresponding to the first upper hole 1a and the second upper hole 2a, the first blind hole m1 and the second blind hole m2 which are relatively steep are formed after the first rapid etching. Hole walls of the first blind hole m1 and the second blind hole m2 can be trimmed during the second slower etching, so that the hole walls are smoother and the change of the overall slope is weak. Furthermore, the slope of the first lower hole 1b and the second lower hole 2b formed is gentle due to a slower etching speed during the second etching, hereby reducing the risk of fracture in the second electrode 182.

This then proceeds to the step B03.

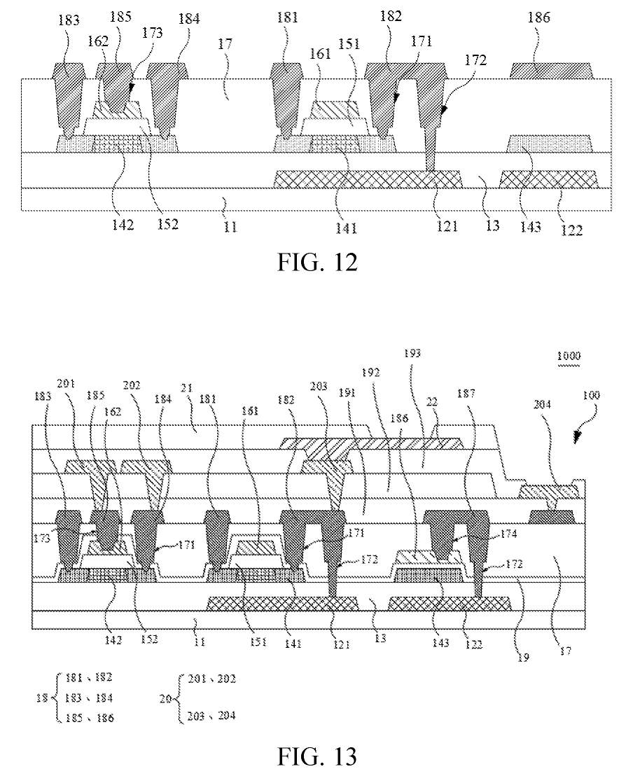

Referring to FIG. 12, at the step B03, a patterned first metal layer 18 is formed on the interlayer dielectric layer 17.

It should be noted that the structure of the display panel 100 in the embodiments corresponding to FIG. 12 is the same as the structure of the display panel 100 in the embodiments corresponding to FIG. 1. Details of the display panel 100 in the embodiments corresponding to FIG. 12 can be referred to in FIGS. 1 and 2, and thus will not be described again herein.

Referring to FIG. 13, accordingly, a display device 1000 is further provided by the embodiments of the present disclosure. The display device includes the display panel 100 described in any one of the above-mentioned embodiments.

Optionally, the display panel 100 can be an electro-luminescent panel, such as an organic light-emitting display panel.

It should be noted that the structure of the display device 1000 in the embodiments of the present disclosure is the same as the structure of the display panel 100 described in any one of the above-mentioned embodiments. Details of the display device 1000 in the embodiments of the present disclosure can be referred to in FIGS. 1 to 12, and thus will not be described again herein.

In the display device 1000 provided by the embodiments of the present disclosure, an etching process is performed on the interlayer dielectric layer 17 using the same photomask to form the first contact hole 171 exposing the first active portion 141 and the second contact hole 172 exposing the light shielding portion 121, thereby saving photomasks. In addition, the depth of the first upper hole 1a of the first contact hole 171 is equal to the depth of the second upper hole 2a of the second contact hole 172, the depth of the first lower hole 1b of the first contact hole 171 is less than the depth of the second lower hole 2b of the second contact hole 172, and the first lower hole 1b of the first contact hole 171 penetrates through the part of the first active portion 141, thereby reducing the degree of the first active portion 141 being etched.

The display device 1000 can be applied to various products and used within such products, including, for example, televisions, notebook computers, monitors, billboards, Internet of Things (IoT) devices, and portable electronic devices such as mobile phones, smartphones, tablet personal computers, mobile communication terminals, electronic notepads, e-books, portable multimedia players (PMP), navigation devices, and ultra-mobile personal computers (UMPC).

Furthermore, in some embodiments, the display device 1000 can be applied to wearable devices and used within such wearable devices, including smartwatches, watch phones, glasses-type displays, and head-mounted displays (HMD). Additionally, in some embodiments, the display device 1000 can be applied to automotive applications such as instrument panels, central dashboards, or the display screens of central information displays (CID) mounted on dashboards, interior mirror displays that replace car side mirrors, and the displays of the entertainment systems for rear-seat passengers arranged on the back of the front seats.

The display panel and the method for manufacturing the display panel provided by the embodiments of the present disclosure have been described in detail above, and the principles and embodiments of the present disclosure have been described herein by applying specific examples, and the description of the above embodiments is only for helping to understand the technical solutions of the present disclosure and the core ideas thereof. In addition, for those skilled in the art, there will be changes in the specific implementations and the scope of application based on the ideas of the present disclosure. In summary, the content of the description should not be understood as limiting the present disclosure.

What is claimed is:

1. A display panel, comprising:
a substrate;
a light shielding portion disposed on the substrate;
a buffer layer disposed on a side of the light shielding portion away from the substrate;
a first active portion disposed on a side of the buffer layer away from the substrate;
a first gate disposed in a different layer from the first active portion; and
an interlayer dielectric layer covering the first active portion and a side of the first gate away from the substrate, wherein the interlayer dielectric layer is provided with a first contact hole and a second contact hole, a depth of the first contact hole is less than a depth of the second contact hole, the first contact hole penetrates through the interlayer dielectric layer and exposes the first active portion, and the second contact hole penetrates through the interlayer dielectric layer and the buffer layer and exposes the light shielding portion;
wherein the first contact hole comprises a first upper hole and a first lower hole, the first lower hole penetrates through a part of the interlayer dielectric layer and a part of the first active portion, the first upper hole is communicated with a side of the first lower hole away from the substrate, and a width of an opening of the first lower hole is less than a width of an opening of the first upper hole; and
wherein the second contact hole comprises a second upper hole and a second lower hole, the second lower hole penetrates through a part of the interlayer dielectric layer and the buffer layer, the second upper hole is communicated with a side of the second lower hole away from the substrate, a width of an opening of the second lower hole is less than a width of an opening of the second upper hole, a depth of the second upper hole is equal to a depth of the first upper hole, and a depth of the second lower hole is greater than a depth of the first lower hole.

2. The display panel according to claim 1, wherein in a thickness direction of the display panel, a distance from an end surface of the opening of the first lower hole to the first active portion is a first distance, and the first distance ranges from 1 nm to 60 nm.

3. The display panel according to claim 2, wherein in the thickness direction of the display panel, a depth of the first lower hole penetrating through the first active portion ranges from 1 nm to 30 nm.

4. The display panel according to claim 3, wherein a distance from the opening of the first lower hole to a hole wall of the first upper hole is a second distance, and the second distance ranges from 0.1 μm to 2 μm.

5. The display panel according to claim 4, wherein a distance from the opening of the second lower hole to a hole wall of the second upper hole is a third distance, and the second distance is equal to the third distance.

6. The display panel according to claim 1, wherein the first lower hole comprises a first sub-hole and a second sub-hole, the first sub-hole is communicated with the first upper hole, the second sub-hole is communicated with a side of the first sub-hole close to the substrate, the second sub-hole is disposed in the first active portion, and a width of an opening of the second sub-hole is less than a width of an opening of the first sub-hole.

7. The display panel according to claim 6, wherein an inclination angle of a hole wall of the first upper hole is greater than an inclination angle of a hole wall of the first sub-hole, and the inclination angle of the hole wall of the first sub-hole is greater than an inclination angle of a hole wall of the second sub-hole.

8. The display panel according to claim 1, further comprising a second active portion, a second gate, a first insulating portion, a second insulating portion, and a first metal layer, wherein the first insulating portion is disposed on a side of the first active portion away from the substrate, the second active portion, the second insulating portion, and the second gate are sequentially stacked on the side of the buffer layer away from the substrate, and the interlayer dielectric layer covers the first gate, the second gate, and the buffer layer;
wherein the first metal layer is disposed on a side of the interlayer dielectric layer away from the substrate, the first metal layer comprises a first electrode, a second electrode, a third electrode, and a fourth electrode, the first electrode is connected to one side of the first active portion through a first first contact hole, one end of the second electrode is connected to the other side of the first active portion through a second first contact hole, the other end of the second electrode is connected to the light shielding portion through one second contact hole, the third electrode is connected to one side of the second active portion through a third first contact hole, and the fourth electrode is connected to the other side of the second active portion through a fourth first contact hole.

9. The display panel according to claim 8, wherein the first metal layer further comprises a first peripheral trace, the interlayer dielectric layer is further provided with a third contact hole exposing the second gate, a depth of the third contact hole is less than the depth of the first contact hole, and the first peripheral trace is connected to the second gate through the third contact hole; and
wherein the third contact hole comprises a third upper hole and a third lower hole, the third lower hole is communicated with a side of the third upper hole close to the substrate, a width of an opening of the third lower hole is less than a width of an opening of the third upper hole, the third lower hole penetrates through a part of the second gate, and a depth of the third lower hole is greater than a depth of the first lower hole penetrating through the first active portion.

10. The display panel according to claim 9, further comprising a second insulating layer, a first electrode plate, a second electrode plate, and a third electrode plate, wherein the first electrode plate is disposed in a same layer as the light shielding portion, the second electrode plate is disposed in a same layer as the first active portion and overlaps with the first electrode plate to form a capacitor, the second insulating layer covers the first gate, the second gate, the second electrode plate, and the buffer layer, the third electrode plate is disposed on a side of the second insulating layer away from the substrate and forms a capacitor with the second electrode plate, and the interlayer dielectric layer covers the second insulating layer and the third electrode plate;
wherein the first metal layer further comprises a connection line, the interlayer dielectric layer is further provided with a fourth contact hole exposing the third electrode plate and another second contact hole exposing the first electrode plate, the first contact hole and the second contact hole further penetrate through the second insulating layer, one end of the connection line is connected to the third electrode plate through the fourth contact hole, and the other end of the connection line is connected to the first electrode plate through the another second contact hole; and
wherein the fourth contact hole comprises a fourth upper hole and a fourth lower hole, the fourth lower hole is communicated with a side of the fourth upper hole close to the substrate, a width of an opening of the fourth lower hole is less than a width of an opening of the fourth upper hole, the fourth lower hole penetrates through a part of the third electrode plate, and a depth of the fourth lower hole is greater than the depth of the first lower hole penetrating through the first active portion.

11. A method for manufacturing a display panel, comprising following steps:
forming a light shielding portion, a buffer layer, a first active portion, a first insulating portion, a first gate, and an interlayer dielectric layer on the substrate in sequence; and
performing two dry etching processes on the interlayer dielectric layer using a same photomask to form a first contact hole and a second contact hole, wherein a depth of the first contact hole is less than a depth of the second contact hole, the first contact hole penetrates through the interlayer dielectric layer and exposes the first active portion, the second contact hole penetrates through the interlayer dielectric layer and the buffer layer and exposes the light shielding portion, the first contact hole comprises a first upper hole and a first lower hole, the first lower hole penetrates through a part of the interlayer dielectric layer and a part of the first active portion, the first upper hole is communicated with a side of the first lower hole away from the substrate, a width of an opening of the first lower hole is less than a width of an opening of the first upper hole, the second contact hole comprises a second upper hole and a second lower hole, the second lower hole penetrates through a part of the interlayer dielectric layer and the buffer layer, the second upper hole is communicated with a side of the second lower hole away from the substrate, a width of an opening of the second lower hole is less than a width of an opening of the second upper hole, a depth of the second upper hole is equal to a depth of the first upper hole, and a depth of the second lower hole is greater than a depth of the first lower hole.

12. The method for manufacturing the display panel according to claim 11, wherein the step of performing two dry etching processes on the interlayer dielectric layer using the same photomask to form the first contact hole and the second contact hole comprises following steps:
performing a first dry etching process on the interlayer dielectric layer using the photomask to form a first blind hole corresponding to the first active portion and a second blind hole corresponding to the light shielding portion, wherein a depth of the first blind hole is equal to a depth of the second blind hole, and a distance from a bottom of the first blind hole to the first active portion is a set distance, and the set distance ranges from 10 nm to 80 nm; and
performing a second dry etching process on the interlayer dielectric layer using the same photomask to form the first contact hole and the second contact hole, wherein a distance from an end surface of the opening of the first lower hole to the first active portion is a first distance, the first distance ranges from 1 nm to 60 nm, and an etching rate of the second dry etching process on the interlayer dielectric layer is greater than an etching rate of the second dry etching process on the first active portion.

13. A display device comprising a display panel, wherein the display panel comprises:
a substrate;
a light shielding portion disposed on the substrate;
a buffer layer disposed on a side of the light shielding portion away from the substrate;
a first active portion disposed on a side of the buffer layer away from the substrate;
a first gate disposed in a different layer from the first active portion; and
an interlayer dielectric layer covering the first active portion and a side of the first gate away from the substrate, wherein the interlayer dielectric layer is provided with a first contact hole and a second contact hole, a depth of the first contact hole is less than a depth of the second contact hole, the first contact hole penetrates through the interlayer dielectric layer and exposes the first active portion, and the second contact hole penetrates through the interlayer dielectric layer and the buffer layer and exposes the light shielding portion;
wherein the first contact hole comprises a first upper hole and a first lower hole, the first lower hole penetrates through a part of the interlayer dielectric layer and a part of the first active portion, the first upper hole is communicated with a side of the first lower hole away from the substrate, and a width of an opening of the first lower hole is less than a width of an opening of the first upper hole; and
wherein the second contact hole comprises a second upper hole and a second lower hole, the second lower hole penetrates through a part of the interlayer dielectric layer and the buffer layer, the second upper hole is communicated with a side of the second lower hole away from the substrate, a width of an opening of the second lower hole is less than a width of an opening of the second upper hole, a depth of the second upper hole is equal to a depth of the first upper hole, and a depth of the second lower hole is greater than a depth of the first lower hole.

14. The display device according to claim 13, wherein in a thickness direction of the display panel, a distance from an end surface of the opening of the first lower hole to the first active portion is a first distance, and the first distance ranges from 1 nm to 60 nm.

15. The display device according to claim 14, wherein in the thickness direction of the display panel, a depth of the first lower hole penetrating through the first active portion ranges from 1 nm to 30 nm.

16. The display device according to claim 15, wherein a distance from the opening of the first lower hole to a hole wall of the first upper hole is a second distance, and the second distance ranges from 0.1 μm to 2 μm.

17. The display device according to claim 16, wherein a distance from the opening of the second lower hole to a hole wall of the second upper hole is a third distance, and the second distance is equal to the third distance.

18. The display device according to claim 13, wherein the first lower hole comprises a first sub-hole and a second sub-hole, the first sub-hole is communicated with the first upper hole, the second sub-hole is communicated with a side of the first sub-hole close to the substrate, the second sub-hole is disposed in the first active portion, and a width of an opening of the second sub-hole is less than a width of an opening of the first sub-hole.

19. The display device according to claim 18, wherein an inclination angle of a hole wall of the first upper hole is greater than an inclination angle of a hole wall of the first sub-hole, and the inclination angle of the hole wall of the first sub-hole is greater than an inclination angle of a hole wall of the second sub-hole.

20. The display device according to claim 13, wherein the display panel further comprises a second active portion, a second gate, a first insulating portion, a second insulating portion, and a first metal layer, the first insulating portion is disposed on a side of the first active portion away from the substrate, the second active portion, the second insulating portion, and the second gate are sequentially stacked on the side of the buffer layer away from the substrate, and the interlayer dielectric layer covers the first gate, the second gate, and the buffer layer; and
wherein the first metal layer is disposed on a side of the interlayer dielectric layer away from the substrate, the first metal layer comprises a first electrode, a second electrode, a third electrode, and a fourth electrode, the first electrode is connected to one side of the first active portion through a first first contact hole, one end of the second electrode is connected to the other side of the first active portion through a second first contact hole, the other end of the second electrode is connected to the light shielding portion through one second contact hole, the third electrode is connected to one side of the second active portion through a third first contact hole, and the fourth electrode is connected to the other side of the second active portion through a fourth first contact hole.
